(19) United States
(12) Patent Application Publication
(10) Pub. No.: US 2006/0054903 A1
(43) Pub. Date: Mar. 16, 2006

(54) Transparent solid-state structure for diagnostics of fluorescently labeled biomolecules

(76) Inventors: Mitchel J. Doktycz, Knoxville, TN (US); Robert J. Warmack, Knoxville, TN (US)

Correspondence Address: UT-Battelle, LLC;Office of Intellectual Property, One Bethal Valley Road, 4500N, MS-6258, Oak Ridge, TN, 37831, US

(21) Appl. No.: 10/942,660

(22) Filed: Sep. 16, 2004

(51) Int. Cl. H01L 33/00; H01L 31/12; H01L 27/15; H01L 29/161; H01L 31/153

(52) U.S. Cl. 257/84

(57) ABSTRACT

Fluorescence modification, meaning either fluorescence enhancement or fluorescence diminishment, is obtained in a transparent layer structure comprised of a substrate, a dielectric layer and a fluorophore-labeled biomolecule layer. A metal particle layer is positioned in the layer structure a distance of 200-500 nm from the fluorophore-labeled biomolecule layer. Separation distances between 200 and 500 nanometers can be used to enhance or diminish fluorescence. All of the layers may be made transparent so that microscopic viewing of the fluorescence is possible from either side of the layer structure.

### STATEMENT REGARDING FEDERALLY SPONSORED RESEARCH OR DEVELOPMENT

The United States Government has rights in this invention pursuant to Contract No. DE-AC05-00OR22725 between the United States Department of Energy and UT-Battelle, LLC.

### BACKGROUND OF THE INVENTION

1. Field of Invention

The present invention relates to the diagnostics of biomolecules that have been labeled with fluorescing materials. More particularly, a new fluorescence enhancement or diminishment effect based on the interaction of multiple particles with fluorescing materials is introduced. Practical solid layer structures based on the new fluorescence enhancement or diminishment effect are described.

2. Description of Prior Art

Fluorescence detection technology is an essential tool for modern analytical measurements. Typically, a reagent is tagged with a fluorescing material or is intrinsically fluorescent, and a detection device capable of measuring emitted fluorescence is used. The technology can enable the sensitive detection of reagents to obtain a variety of useful information. For example, fluorescence detection technology is becoming standard for biologically related measurements. It allows for the sensitive detection of a reagent without the harmful effects of radiation, as occurs with the use of radioactive tags. The technology is routinely employed for applications that determine DNA sequence, evaluate RNA expression or analyze proteins. The technology is also applied routinely for identifying and tracing biological materials within cells.

There have been a number of approaches to improving fluorescence detection technology. Many of these approaches seek either the development of fluorescent tags with improved characteristics or are instrumentation-based approaches. Examples are alternative optical arrangements for excitation or detection, different excitation techniques, and methods for photon detection. Some examples of prior technology follow.

W. R. Holland et al, “Method and System for the Enhancement of Fluorescence”, U.S. Pat. No. 4,649,280, Issued Mar. 10, 1987 describes a fluorescence-enhanced chip. Fluorescence intensity in the material can be enhanced using a stack of materials comprising a glass substrate, a film of conductive material, dielectric layer, and fluorescent material film layer.

C. Mayer et al, “Slide-Format Proteomic Biochips Based on Surface-Enhanced Nanocluster-Resonance”, Fresenius J. Anal. Chem. Vol. 371, pp. 238-245, 2001 describes the interaction of fluorophores with a cluster of metal particles at near distances of 5-45 nm. Mayer optionally uses a mirror structure to reflect energy emanating from a cluster.

J. R. Lakowicz, “Radiative Decay Engineering”, U.S. Patent Application Publication No. U.S. 2002/0160400, Publication Date Oct. 31, 2002 describes a materials interaction effect with a fluorescing species that is quite pronounced over short distances. For example, a single nearby metal particle is used to increase the intrinsic radioactive decay rate of a biomolecule. At near distances, from 5 to 200 nm to a metal particle, the intrinsic fluorescence of a biomolecule can be enhanced. By exploiting its intrinsic fluorescence, extrinsic tagging (labeling) of the biomolecule is unnecessary.

T. Akimoto et al, “Fluorescence-Enhanced Chip”, U.S. Pat. No. 6,500,679, Issued Dec. 31, 2002 describes stacked materials that produce a light propagation mode that enhances fluorescence intensity. Materials include a stack of metal film, a dielectric film and a fluorescent material film on a glass substrate. Akimoto improves upon the design of Holland et al by the use of a silicon dioxide dielectric layer. Dielectric thicknesses on the order of 65 nm are identified as being optimal for fluorescence enhancement.

New approaches that improve fluorescence detection technology by improving detection sensitivity, improving the fluorescence yield of the reagent, lowering background fluorescence, lowering the instrumentation costs, or otherwise facilitating the analytical measurements are greatly needed.

We have discovered a new and different effect useful for enhancing or modifying the fluorescence of fluorescing materials or fluorophores. The new fluorescence enhancement effect is based on long-range interactions of fluorophores with multiple metal particles. We have found that fluorescence can be dramatically increased or decreased by the interaction of a plurality of metal particles with the fluorescing materials, provided that the fluorescing materials are separated from the metal particles by relatively large or long-range distances of 200-500 nm. It is our discovery that the interaction of illuminated particles with fluorescing materials at these distances can enhance or diminish the fluorescence, depending upon the material properties and the geometry of the construction. We describe how the effect can be put to practical use for improving fluorescence detection technology.

Our discovery for altering fluorescence enables the construction of very practical structures for diagnostic purposes. For example, a transparent substrate such as a glass microscope slide can be coated with a layer of metal particles followed by a transparent overlayer having a thickness that has been very carefully determined beforehand. A sample containing fluorescing material applied to the overlayer will then have its fluorescence altered by the presence of the multiple metal particles.

### BRIEF SUMMARY OF THE INVENTION

It is a first object of the invention to provide solid-state fluorescence-altering layer structures for analyzing labeled biomolecules.

It is another object of the invention to interpret such structures with conventional fluorescence detection techniques as commonly used in microscopy.

It is another object of the invention to provide multiple layered structures that enhance or diminish the fluorescence emission from a tagged biological reagent.

A preferred embodiment of the invention is a layer structure for fluorescence modification that comprises a substrate, a dielectric layer on at least a portion of the substrate, and a fluorophore-labeled biomolecule layer on at least a portion of the dielectric layer. In addition, a metal particle layer is located within at least a portion of the layer structure. The metal particle layer is positioned within the range of 200 to 500 nanometers from at least a portion of the fluorophore-labeled biomolecule layer.

In another preferred embodiment, a portion of the layer structure is capable of assessing fluorescence modification by providing that portion with only the substrate, the dielectric layer, and the metal particle layer.

### BRIEF DESCRIPTION OF THE DRAWINGS

FIG. 1 shows an arrangement of material layers useful for controlling the fluorescence of a fluorophore-labeled biomolecule layer.

FIG. 2 shows an adhesion layer added to the layer structure of FIG. 1.

FIG. 3 shows an arrangement of material layers useful for controlling the fluorescence of a plurality of fluorophore-labeled biomolecule layers.

FIG. 4 shows another arrangement of material layers useful for controlling the fluorescence of a plurality of fluorophore-labeled biomolecule layers.

FIG. 5 shows a further arrangement of material layers useful for controlling the fluorescence of a plurality of fluorophore-labeled biomolecule layers.

FIG. 6 shows example data and a graphical representation of the controlled fluorescence emission obtained from a layer of metal islands. The top image displays an ink-jetted array of 100 μg/ml TRITC-avidin over a 5-nm average thickness layer of silver particles (left side) and coated with a 300 nm of silicon dioxide (entire slide). The second image is similar but with a 200 nm layer of silicon dioxide. The third image displays a 10 μg/ml solution spotted onto a 100 nm layer of silver (left side) that was coated with 300 nm of silicon dioxide. The bottom panel quantifies the degree of enhancement and diminishment that is observed due to the spacing.

### DETAILED DESCRIPTION OF THE INVENTION

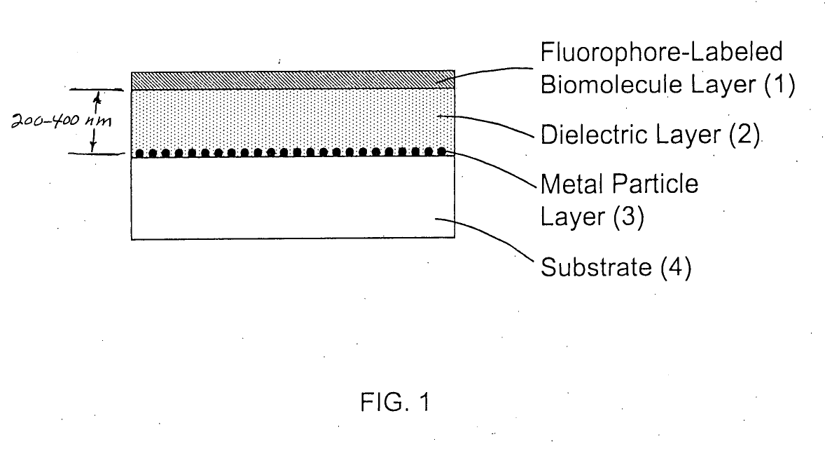

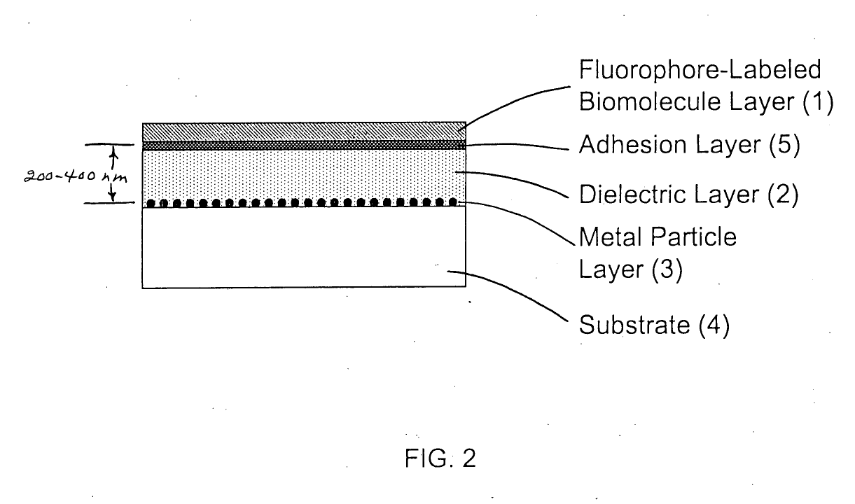

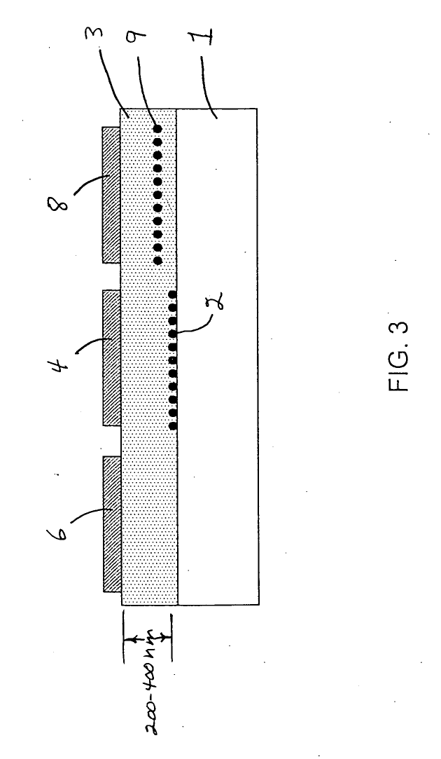

Several preferred embodiments of the invention are shown in FIGS. 1-5. Each of the figures shows a layered structure built up from a substrate 1, a metal particle layer 2, a dielectric layer 3, and a fluorophore-labeled biomolecule layer 4, respectively. FIG. 1 shows the basic layer structure of the invention. FIG. 2 adds an adhesion layer to the basic structure. FIGS. 3-5 illustrate further layer structures in accordance with the invention that may be built up on a common substrate 1.

### Substrate

In FIGS. 1-5, a substrate 1 acts as a base for the active layers. It is preferably transparent to allow use of the layer structure in a transmission scanner or optical microscope so that fluorescence can be observed from either side of the substrate. The substrate 1 can be composed of polished optical material such as glass or fused silica, for example. An optical microscope slide or silicon wafer is also a suitable substrate.

### Metal Particle Layer

In FIGS. 1-5, a layer 2 is comprised of metal particles of a suitable material that allow resonant interaction of the excitation light with the composite structure. Preferred metals include silver and gold. The metal particle layer 2 can be formed on the substrate 1 by deposition using thermal, electron-beam or vacuum sputtering processes. The preferred average thickness of the metal layer 2 is 2-100 nanometers. The metal particle layer may also be annealed by temperature cycling up to several hundred degrees centigrade. This procedure changes the shape and thus the resonance of the metal particle layer 2. The metal particles are separated from each other for thinner coatings and adjoin one another for the thicker coatings. An alternative coating process would be using colloidal metal particles dispersed in a suitable liquid that is then cast upon the substrate. The particles would remain as a residue when the liquid is made to evaporate.

One feature of the metal layer 2 will become apparent in use. This has to do with the fact that the glass microscope slide is a standard for biological applications from microscopy to DNA microarray analyses. The metal particle layer used in our invention can be made with a small amount of metal so as to be transparent to light. It is this feature, together with the fact that in most instances the other layers can also be made transparent, that allows the entire layer structure to be made transparent to light. Thus, the use of the metal particle layer enables transparency through the whole structure, allowing viewing by microscope or microarray means from either the top or bottom of the structure.

### Dielectric Layer

The dielectric layer 3 is a solid layer located between the metal layer 2 and the fluorophore labeled biomolecule layer 4. The dielectric layer 3 can be formed by a variety of processes. Preferably, it is deposited by thermal, electron-beam, sputtering or chemical-vapor deposition techniques. The material is preferably silica but can also be chosen from other transparent dielectric materials. Alternatively, a suitable spin-coated polymer film may be used. Additional processes may subsequently be applied to planarize the layer thickness. The dielectric layer 3 is used to maintain the fluorophore labeled biomolecules an exact predetermined distance from the metal particle layer consistent with our fluorescence modification discovery, (i.e., enhancing and/or diminishing) described earlier. The operative separation distance for enhanced fluorescence in our invention is 200 nm to 500 nm. Below 200 nm, fluorescent diminishment, up to and including quenching, tends to dominate. Above 500 nm, the effect of the metal particle layer is substantially reduced. From our preliminary experiments using these materials, the optimum thickness for mid-visible fluorophores is around 300 nm for silica on a silver metal particle layer.

The thickness of the dielectric layer 3 also provides another mechanism to select a particular fluorescence. For example, two or more fluorophores that fluoresce at different wavelengths in a mixture could be identified or analyzed by depositing the mixture onto various dielectric layers that differ in their thicknesses. A selected fluorophore may be selectively enhanced or diminished with an appropriate dielectric layer thickness.

In FIG. 3, the metal particle layer 9 is not deposited on the substrate 1 in the manner of metal particle layer 2. Rather, it is deposited within the dielectric layer 3 an exact predetermined distance from the fluorophore-labeled biomolecule layer 8. A substrate built up in the manner of FIG. 3 allows the direct comparison of fluorescence intensity with two or more predefined dielectric layer thicknesses and also with the fluorescence obtained without the presence of a metal particle layer. This is shown in FIG. 3 by the fluorophore-labeled biomolecule layer 6 and the absence of a metal particle layer beneath the biomolecule layer 6.

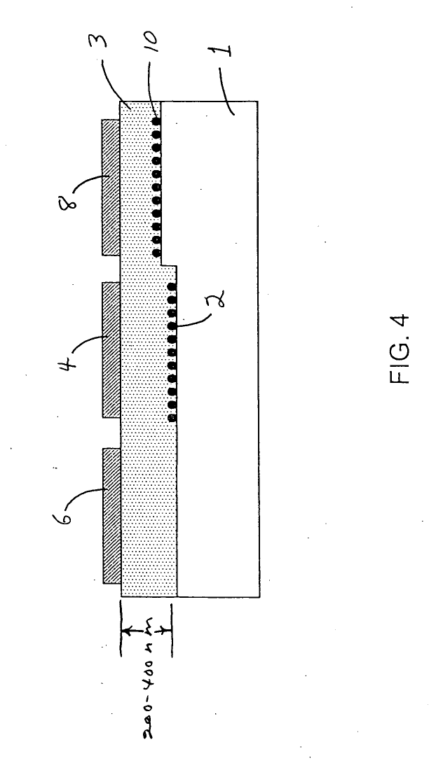

FIG. 4 shows an alternative means of providing more than one separation distance or a varying separation distance between a metal particle layer and a fluorophore-labeled biomolecule layer. In FIG. 4, the substrate 1 has more than one surface height for the two metal particle layers 2, 10. A gradually varying substrate thickness can also be used.

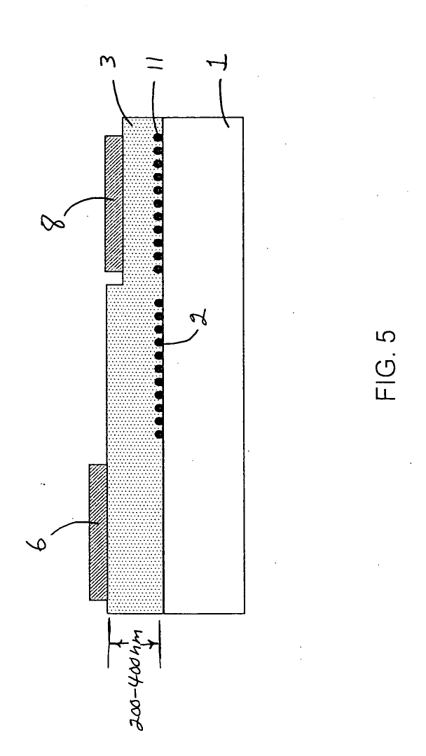

FIG. 5 illustrates another way of obtaining more than one separation distance between a metal particle layer and a fluorophore-labeled biomolecule layer. In FIG. 5, a dielectric layer 3 with more than one thickness is shown for the two metal particle layers 2, 11. A dielectric layer 3 having a gradually varying thickness could also be used.

In FIG. 1, the prescribed dielectric layer 3 thickness also depends on the emission wavelength of the fluorescing material and the dielectric properties of the separating material and the metal particle layer 2. In the case of a silver particle metal layer, a silicon dioxide dielectric layer, a fluorescence emitter in the wavelength range of 575-650 nm, and a separation distance in the range of 275-350 nm will enhance the fluorescence. Separation distances shorter than 275 nm can be used to diminish the fluorescence emission.

### Biomolecule/Fluorophore Layer

In FIG. 1, the fluorophore-labeled biomolecule layer 4 is spaced a predetermined distance from the metal particle layer 2 by the dielectric layer 3. The biomolecule layer 4 can be at least one of the class of biomolecule reagents that includes nucleic acids, proteins, carbohydrates, lipids or small molecules that are associated with a fluorophore label. The fluorophore-labeled biomolecule layer 4 may be continuous as shown in FIGS. 1 and 2 or specifically positioned in the built-up layer structures shown in FIGS. 3-5.

### Adhesion Layer

Referring to FIG. 2 an adhesion layer 5 may be added, if needed, between the dielectric layer 3 and the biomolecule/fluorophore layer 4 to provide better observation and control of the diagnostic measurements. The adhesion layer 5 may be added to the dielectric layer 3 to insure that the fluorophore-labeled biomolecule layer 4 is firmly and selectively affixed to the dielectric layer 3. Such an adhesion layer may be a distinct layer as FIG. 2 shows, or it may be formed by chemical treatment of the dielectric layer. An example of the latter is to chemically derivatize the surface of the dielectric layer 3 with a chemical group such as amines, thiols, or carboxylic acids that permits binding to biomolecules. A silane reagent, such as amino-propyl-trimethoxysilane, is an example. The bound biomolecule may be used to diagnostically capture a fluorescently labeled biomolecule.

### EXAMPLES

An example of a structure that can be made for fluorescence enhancement and diminishment is given. Fused silica slides are cleaned by solvent and oxygen-plasma treatments. The slides are partially coated with silver particles ranging in average thickness of 5-100 nanometers using a shuttered electron-beam evaporator. The slides are then heated and coated with 100-500-nanometer-thick silica in a plasma-enhanced chemical-vapor-deposition chamber. The structure can then be treated with a reagent such as poly-L-lysine to serve as an adhesion layer. An amine containing DNA strand can be selectively positioned on the structure using a manual pipette or robotic spotting and crosslinked to the adhesion layer using glutaraldehyde. After washing of the structure, a solution of fluorescently labeled DNA target strands will be immobilized onto the structure. Different DNA targets, which may contain different fluorophore labels, can be used. Depending on the fluorescence emission properties, the dielectric materials, and the dielectric layer thickness, the fluorescence emission of a fluorophore will be enhanced or diminished. Diminishment is observed in the thinner silica dielectric layers while thicker dielectric layers enhance the fluorescence.

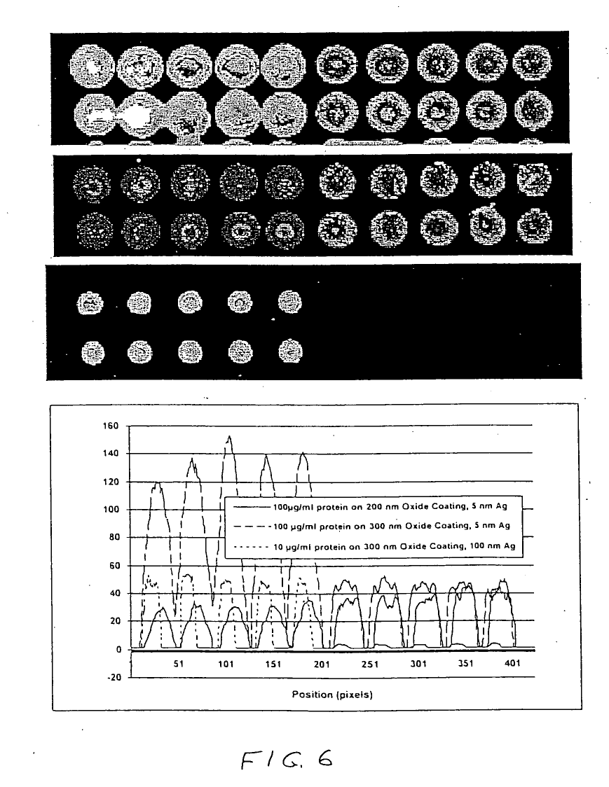

FIG. 6 shows example data and a graphical representation of the controlled fluorescence emission obtained from such structures. The top image displays an ink-jetted array of 100 μg/ml TRITC-avidin over a 5-nm average thickness layer of silver (left side) and coated with a 300 nm of silicon dioxide (entire slide). The second image is similar but with a 200 nm layer of silicon dioxide. The third image displays a 10 μg/ml solution spotted onto a 100-nm average thickness layer of silver (left side) that was coated with 300 nm of silicon dioxide. The bottom panel quantifies the enhancement and diminishment that is observed due to the spacing and the presence or absence of a metal particle layer.

An important aspect of the invention is providing a portion of the layer structure with only the substrate, dielectric layer, and metal particle layer present. This is illustrated in the center portion of FIG. 5, in the region above metal particle layer 2, where the fluorophore-labeled biomolecule layer is absent. This center portion of the layer structure is capable of assessing fluorescence modification by providing a reference signal of the light transmission through the structure absent the fluorophore-labeled biomolecule layer.

What has been described are structures that provide an inexpensive approach to controlling fluorescence emission relative to instrumentation-based approaches, is compatible with instruments typically used for fluorescence microscopy or microarray readout, and can be designed to enhance and/or diminish fluorescence emission.

The layer structures described herein could be used with bioassays to greatly enhance the fluorescent signal and enable the detection of lower concentrations of analytes. The method could also permit analyses of much smaller samples to conserve valuable resources.

While there has been shown and described what are at present considered the preferred embodiments of the invention, it will be obvious to those skilled in the art that various changes and modifications can be prepared therein without departing from the scope of the inventions defined by the appended claims.

1. A layer structure for fluorescence modification comprising:
a substrate;
a dielectric layer on at least a portion of said substrate;
a fluorophore-labeled biomolecule layer on at least a portion of said dielectric layer; and
a metal particle layer within at least a portion of the layer structure, said metal particle layer positioned 200 to 500 nanometers from at least a portion of said fluorophore-labeled biomolecule layer.

2. The layer structure of claim 1 wherein said substrate is transparent.

3. The layer structure of claim 1 wherein said substrate is glass.

4. The layer structure of claim 1 wherein said substrate is quartz.

5. The layer structure of claim 1 wherein said substrate is silicon.

6. The layer structure of claim 1 wherein said metal particle layer is transparent.

7. The layer structure of claim 1 wherein said metal particle layer is gold.

8. The layer structure of claim 1 wherein said metal particle layer is silver.

9. The layer structure of claim 1 wherein said dielectric layer is transparent.

10. The layer structure of claim 1 wherein said dielectric layer is an adhesion layer for adhering said fluorophore-labeled biomolecule layer to at least a portion of said metal particle layer.

11. The layer structure of claim 1 additionally including at least one adhesion layer for adhering said fluorophore-labeled biomolecule layer to at least a portion of said dielectric layer.

12. The layer structure of claim 1 wherein said fluorophore-labeled biomolecule layer is a liquid.

13. The layer structure of claim 1 wherein said fluorophore-labeled biomolecule layer is a liquid in a transparent container.

14. The layer structure of claim 1 wherein the position of said metal particle layer is selected to produce enhancement of the fluorescence of said fluorophore-labeled biomolecule layer.

15. The layer structure of claim 1 wherein the position of said metal particle layer is selected to produce diminishment of the fluorescence of said fluorophore-labeled biomolecule layer.

16. The layer structure of claim 1 wherein said fluorophore-labeled biomolecule layer is made by the capture of fluorescent-labeled biomolecules from the surroundings by another biomolecule.

17. The layer structure of claim 1 wherein said substrate has more than one thickness.

18. The layer structure of claim 1 wherein said substrate has a varying thickness.

19. The layer structure of claim 1 wherein said dielectric layer has more than one thickness.

20. The layer structure of claim 1 wherein said dielectric layer has a varying thickness.

21. The layer structure of claim 1 wherein a portion of said layer structure is capable of assessing fluorescence modification, said portion comprising only said substrate, said dielectric layer, and said metal particle layer.
